(19) United States
(12) Patent Application Publication
(10) Pub. No.: US 2026/0182230 A1
(43) Pub. Date: Jun. 25, 2026

(54) DISPLAY DEVICE

(71) Applicant: LG Display Co., Ltd., Seoul (KR)

(72) Inventors: Jungeun LEE, Seoul (KR); HwanKeon LEE, Gimpo-si (KR); Jeongbeom LEE, Seoul (KR); Junhyeok LEE, Seoul (KR)

(73) Assignee: LG Display Co., Ltd., Seoul (KR)

(21) Appl. No.: 19/388,838

(22) Filed: Nov. 13, 2025

(30) Foreign Application Priority Data
Dec. 23, 2024 (KR) 10-2024-0194353

(51) Int. Cl. H10K 59/80; H10K 59/40

(52) U.S. Cl. CPC H10K 59/8792; H10K 59/40

(57) ABSTRACT

A display device includes a substrate having an active area with a plurality of sub pixels and a non-active area adjacent to the active area. A plurality of light emitting elements is disposed in the plurality of sub-pixels on the substrate, and an encapsulation unit covers the light emitting elements. A touch sensing unit having a plurality of touch electrodes is disposed on the encapsulation unit, and a black matrix is disposed on the touch sensing unit. A plurality of anti-deposition patterns is disposed to at least partially overlap the black matrix, and a plurality of metal patterns is disposed between the anti-deposition patterns. An organic dye layer is disposed on the black matrix. Through this structure, the reflectance of external light in both the emission area and the non-emission area of the plurality of light emitting elements can be reduced.

### CROSS-REFERENCE TO RELATED APPLICATIONS

This application claims the priority of Korean Patent Application No. 10-2024-0194353 filed on Dec. 23, 2024, in the Korean Intellectual Property Office, the disclosure of which is incorporated herein by reference.

### BACKGROUND

### Technical Field

The present disclosure relates to a display device, and more particularly, to a display device capable of reducing reflection of external light.

### Description of the Related Art

As it enters the information age, the field of display devices that visually display electrical information signals is rapidly developing, and research is being conducted to develop performances such as thinning, weight reduction, and low power consumption for various display devices.

Representative display devices include a liquid crystal display (LCD), a field emission display (FED), an electro-wetting display (EWD), and an organic light emitting display (OLED).

An electroluminescent display device represented by an organic light emitting display device is a self-emitting display device and does not require a separate light source unlike a liquid crystal display device. Therefore, the electroluminescent display device can be manufactured to have a light weight and a small thickness. In addition, the electroluminescent display device is advantageous in terms of power consumption because the electroluminescent display device operates at a low voltage. Further, the electroluminescent display device is expected to be utilized in various fields because the electroluminescent display device exhibits excellent performance in terms of color reproduction, response speeds, viewing angles, and contrast ratios (CRs).

### BRIEF SUMMARY

The present disclosure relates to a display device that reduces external light reflection and simplifies fabrication. Various configurations may be employed, including selective placement of metal patterns, use of fluorine-containing anti-deposition patterns, and provision of an integrated organic dye layer. These and other structural arrangements may contribute individually or in combination to improved optical performance, reduced process complexity, and enhanced manufacturing efficiency. The metal patterns are arranged in the emission areas and positioned on the same or a lower layer as the black matrix, preventing reflection in non-emission areas while maintaining brightness in light-emitting regions. The anti-deposition patterns, formed from fluorine-based materials, define metal deposition regions without requiring additional masking steps, thereby reducing manufacturing complexity and production cost.

An organic dye layer is applied over both emission and non-emission areas using an inkjet or photo process. This layer replaces conventional color filters and polarizers, transmitting red, green, and blue light while suppressing reflection. As a result, the display thickness, process time, and cost are reduced, and both contrast and visibility are improved. Inorganic buffer layers may be included between organic materials to prevent chemical interference and enhance device stability and optical reliability.

The described structure integrates optical performance and process efficiency within a single configuration. By eliminating separate polarizers and color filters, optimizing the arrangement of metal patterns, and employing low-temperature black matrix and black bank layers, the display achieves improved luminance, reduced reflectance, and lower power consumption compared to conventional organic light-emitting diode displays that require additional optical films and complex patterning processes.

Various embodiments of the present disclosure provide a display device capable of reducing reflectance of external light.

Various embodiments of the present disclosure provide a display device capable of reducing a process cost and a process time of the display device.

Technical benefits of the present disclosure are not limited to the above-mentioned benefits, and other benefits, which are not mentioned above, can be clearly understood by those skilled in the art from the following descriptions.

According to an aspect of the present disclosure, a display device includes a substrate including an active area in which a plurality of sub pixels is disposed and a non-active area surrounding the active area, a plurality of light emitting elements disposed in the plurality of sub pixels on the substrate, an encapsulation unit disposed to cover the plurality of light emitting elements, a touch sensing unit disposed on the encapsulation unit and including a plurality of touch electrodes, a black matrix disposed on the touch sensing unit, a plurality of anti-deposition patterns disposed to at least partially overlap the black matrix, a plurality of metal patterns disposed between the plurality of anti-deposition patterns, and an organic dye layer disposed on the black matrix.

According to another aspect of the present disclosure, a display device includes a substrate, a plurality of light emitting elements disposed on the substrate, an encapsulation unit disposed to cover the plurality of light emitting elements, a touch sensing unit disposed on the encapsulation unit and including a plurality of touch electrodes, a plurality of metal patterns disposed on the touch sensing unit to overlap an organic layer of the plurality of light emitting elements, a plurality of fluorine-containing patterns disposed between the plurality of metal patterns on a plane, a black matrix disposed to overlap the plurality of fluorine-containing patterns, and an organic dye layer disposed on the black matrix, in which the plurality of metal patterns is disposed on the same layer as the black matrix or lower layer than the black matrix.

Other detailed matters of the embodiments are included in the detailed description and the drawings.

In the display device of the present disclosure, a plurality of metal patterns is disposed to correspond to the emission areas of the plurality of light emitting elements, and an organic dye layer is disposed to overlap the emission areas and the non-emission areas of the plurality of light emitting elements, thereby improving reflectance in the emission areas of the plurality of light emitting elements.

According to the present disclosure, the display device does not dispose an unnecessary metal layer or a metal pattern in the non-emission area of the plurality of light emitting elements, thereby reduce reflectance in the non-emission area of the plurality of light emitting elements.

In the display device of the present disclosure, a buffer layer is disposed between the plurality of anti-deposition patterns and the organic dye layer to prevent interference between the plurality of anti-deposition patterns made of an organic material and the organic dye layer.

In the display device of the present specification, the mask process may be omitted by forming the organic dye layer by an application process such as an inkjet process, and thus process optimization such as reducing process cost and process time may be possible.

The effects according to the present disclosure are not limited to the contents exemplified above, and more various effects are included in the present specification.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a block diagram illustrating a display device according to an exemplary embodiment of the present disclosure.

FIG. 2 is a view schematically illustrating a circuit configuration of a sub-pixel according to an exemplary embodiment of the present disclosure.

FIG. 3 is a cross-sectional view taken along the line III-III′ of FIG. 1.

FIG. 4 is a schematic cross-sectional view of a display device according to another embodiment of the present specification.

FIG. 5 is a schematic cross-sectional view of a display device according to still another exemplary embodiment of the present disclosure.

FIG. 6 is a schematic cross-sectional view of a display device according to still another exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on,” “above,” “below,” and “next,” one or more parts may be positioned between the two parts unless the terms are used with the term “immediately” or “directly.”

When an element or layer is disposed “on” another element or layer, another layer or another element may be interposed directly on the other element or therebetween.

Although the terms “first,” “second,” and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the disclosure.

As used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

The features of various embodiments of the present disclosure can be partially or entirely adhered to or combined with each other and can be interlocked and operated in technically various ways, and the embodiments can be carried out independently of or in association with each other.

Hereinafter, an exemplary embodiments of the present disclosure will be described in detail with reference to accompanying drawings.

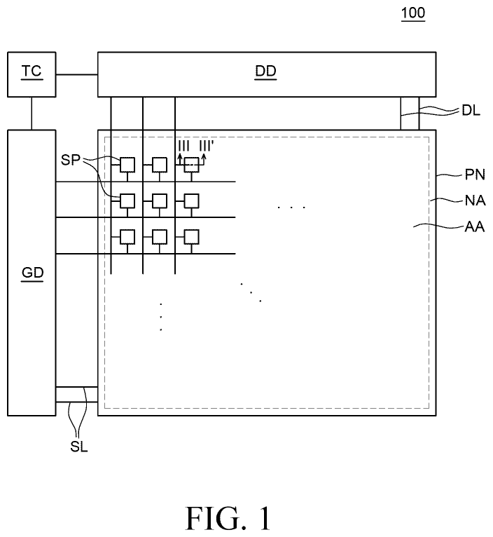

FIG. 1 is a block diagram illustrating a display device according to an exemplary embodiment of the present disclosure. In FIG. 1, for the convenience of description, among various components of the display device 100, only a display panel PN, a gate driver GD, a data driver DD, and a timing controller TC are illustrated.

Referring to FIG. 1, a display device 100 includes a display panel PN including a plurality of sub pixels SP, a gate driver GD and a data driver DD which supply various signals to the display panel PN, and a timing controller TC which controls the gate driver GD and the data driver DD.

The gate driver GD supplies a plurality of scan signals to a plurality of scan lines SL according to a plurality of gate control signals provided from the timing controller TC. FIG. 1 illustrates that one gate driver GD is disposed to be spaced apart from one side of the display panel PN. However, the number and arrangement of the gate drivers GD are not limited thereto.

The data driver DD supplies a data voltage to a plurality of data lines DL according to a plurality of data control signals and image data provided from the timing controller TC. The data driver DD may convert image data into a data voltage using a reference gamma voltage and supply the converted data voltage to a plurality of data lines DL.

The timing controller TC aligns image data input from the outside and supplies the image data to the data driver DD. The timing controller TC may generate a gate control signal and a data control signal by using a synchronization signal input from the outside, for example, a dot clock signal, a data enable signal, and a horizontal/vertical synchronization signal. Further, the timing controller TC supplies the generated gate control signal and data control signal to the gate driver GD and the data driver DD, respectively, to control the gate driver GD and the data driver DD.

The display panel PN is configured to display images to a user and includes a plurality of sub-pixels SP. In the display panel PN, the plurality of scan lines SL and the plurality of data lines DL may cross each other, and the plurality of sub pixels SP may be formed at intersections of the scan line SL and the data line DL.

In the display panel PN, an active area AA and a non-active area NA may be defined.

The active area AA is an area in which images are displayed in the display device 100. In the active area AA, a plurality of sub pixels SP constituting a plurality of pixels and a pixel circuit for driving the plurality of sub pixels SP may be disposed. The plurality of sub-pixels SP is a minimum unit constituting the active area AA, and n sub-pixels SP may form one pixel. In each of the plurality of sub pixels SP, a thin film transistor for driving the plurality of light emitting elements is disposed so that the plurality of sub pixels SP may independently emit light. For example, the plurality of sub-pixels may include a first sub-pixel, a second sub-pixel, and a third sub-pixel that emit light of different colors. For example, the first sub-pixel may be a red sub-pixel that emits red light, the second sub-pixel may be a green sub-pixel that emits green light, and the third sub-pixel may be a blue sub-pixel that emits blue light, but is not limited thereto.

The plurality of light emitting elements may be differently defined depending on the type of the display panel PN. For example, when the display panel PN is an organic light emitting display panel, the light emitting element may be an organic light emitting diode.

In the active area AA, a plurality of signal lines for transmitting various signals to the plurality of sub-pixels SP is disposed. For example, the plurality of signal lines may include a plurality of data lines DL which supplies a data voltage to each of the plurality of sub pixels SP, a plurality of scan lines SL which supplies a scan signal to each of the plurality of sub pixels SP, and the like. The plurality of scan lines SL may extend in one direction in the active area AA and be connected to the plurality of sub pixels SP, and the plurality of data lines DL may extend in a direction different from the one direction in the active area AA and be connected to the plurality of sub pixels SP. In addition, in the active area AA, a low potential power line, a high potential power line, and the like may be further disposed, but are not limited thereto.

The non-active area NA is an area where an image is not displayed and may be defined as an area extending from the active area AA. In the non-active area NA, a link line and a pad electrode for transmitting a signal to the sub pixel SP of the active area AA, or a driving IC, such as a gate driver IC or a data driver IC, may be disposed.

Meanwhile, a driver such as a gate driver GD, a data driver DD, and a timing controller TC may be connected to the display panel PN in various ways. For example, the gate driver GD may be mounted in the non-active area NA in a gate-in-panel (GIP) manner or mounted between the plurality of sub pixels SP in the active area AA in a gate-in-active area (GIA) manner.

For example, the data driver DD and the timing controller TC are formed on separate flexible film and printed circuit board, and the display panel PN, the data driver DD, and the timing controller TC may be electrically connected by bonding the flexible film and the printed circuit board to the pad electrode formed in the non-active area NA of the display panel PN.

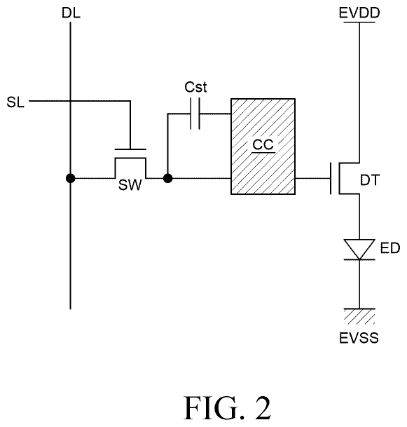

FIG. 2 is a view schematically illustrating a circuit configuration of a sub-pixel according to an embodiment of the present disclosure.

Referring to FIG. 2, one sub-pixel may include a switching transistor SW, a driving transistor DT, a capacitor Cst, a compensation circuit CC, and an organic light emitting element ED.

For example, the switching transistor SW may perform a switching operation so that a data signal supplied through the data line DL is stored in the capacitor Cst as a data voltage in response to a scan signal supplied through the scan line SL. Further, for example, the driving transistor DT may operate such that a driving current flows between the high potential power line EVDD and the low potential power line EVSS according to a data voltage stored in the capacitor Cst. Further, the organic light emitting element ED may operate to emit light according to a driving current formed by the driving transistor DT.

The compensation circuit CC is a circuit added to the sub-pixel to compensate for a threshold voltage of the driving transistor DT. The compensation circuit CC may include one or more transistors. The configuration of the compensation circuit CC may vary depending on an external compensation method.

The sub pixel illustrated in FIG. 2 is configured by a 2T (transistor) 1C (capacitor) structure including a switching transistor SW, a driving transistor DT, a capacitor Cst, and a light emitting element ED. When the compensation circuit 135 is added, the sub pixel may be configured in various forms, such as 3T1C, 4T2C, 5T2C, 6T1C, 6T2C, 7T1C, and 7T2C.

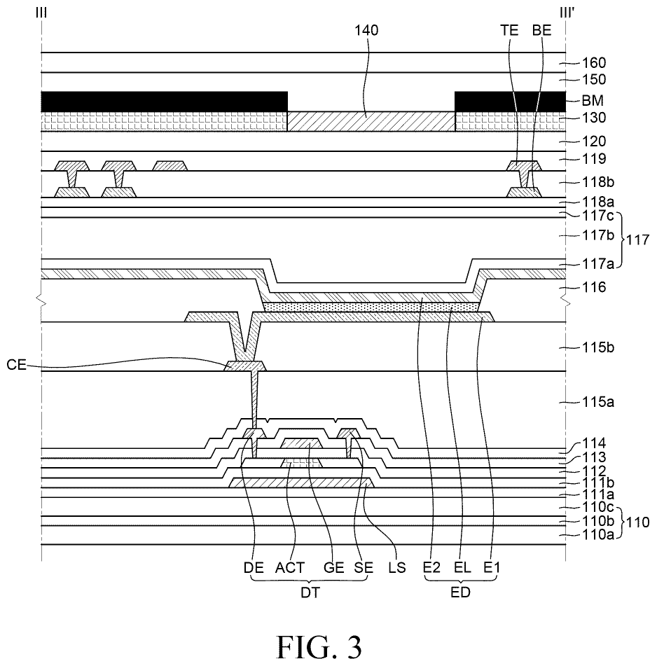

FIG. 3 is a cross-sectional view taken along the line III-III′ of FIG. 1. In FIG. 3, for the convenience of description, only components included in one sub pixel SP disposed in the active area AA are shown.

Referring to FIG. 3, the substrate 110 is a component for supporting various components included in the display device 100 and may be formed of an insulating material. The substrate 110 may include a first substrate 110a, an insulating layer 110b, and a second substrate 110c. The insulating layer 110b may be disposed between the first substrate 110a and the second substrate 110c. As described above, the substrate 110 is configured by the first substrate 110a, the second substrate 110c, and the insulating layer 110b to suppress moisture permeation. For example, the first substrate 110a and the second substrate 110c may be polyimide (PI) substrates.

The first buffer layer 111a is disposed on the substrate 110. The first buffer layer 111a may reduce permeation of moisture, oxygen, or impurities through the substrate 110. For example, the first buffer layer 111a may be configured as a single layer or multilayer made of silicon oxide (SiOₓ) or silicon nitride (SiNₓ). However, the present disclosure is not limited thereto.

The light shielding layer LS is disposed on the first buffer layer 111a in each of the plurality of sub-pixels. The light shielding layer LS blocks light incident onto an active layer ACT of the driving transistor DT to be described below from a lower portion of the substrate 110. Light which is incident onto the active layer ACT of the driving transistor DT is blocked by the light shielding layer LS to minimize a leakage current.

The second buffer layer 111b is disposed on the substrate 110 and the light shielding layer LS. The second buffer layer 111b may reduce penetration of moisture or impurities through the substrate 110. For example, the second buffer layer 111b may be configured by a single layer or a double layer of silicon oxide (SiOₓ) or silicon nitride (SiNₓ), but is not limited thereto. However, the second buffer layer 111b may be omitted depending on the type of substrate 110 or the type of transistor, but is not limited thereto.

The driving transistor DT of each of the plurality of sub pixels SP is disposed on the second buffer layer 111b. The driving transistor DT is a transistor for controlling a driving current supplied to the light emitting element ED.

The driving transistor DT includes an active layer ACT, a gate electrode GE, a source electrode SE, and a drain electrode DE.

The active layer ACT of the driving transistor DT may be disposed on the second buffer layer 111b. For example, the active layer ACT may be formed of polysilicon (p-Si), amorphous silicon (a-Si), or an oxide semiconductor, but is not limited thereto.

The gate insulating layer 112 may be disposed on the active layer ACT. The gate insulating layer 112 is an insulating layer which insulates the active layer ACT from the gate electrode GE and may be formed of silicon oxide (SiOₓ), silicon nitride (SiNₓ), or a double layer thereof.

Further, the gate electrode GE of the driving transistor DT may be disposed on the gate insulating layer 112. The gate electrode GE is disposed on the gate insulating layer 112 so as to overlap the active layer ACT. The gate electrode GE may be formed of various conductive materials, such as magnesium (Mg), aluminum (Al), nickel (Ni), chromium (Cr), molybdenum (Mo), tungsten (W), gold (Au), or an alloy thereof, but is not limited thereto.

The interlayer insulating layer 113 may be disposed to cover the gate electrode GE. The interlayer insulating layer 113 is an insulating layer which protects components below the interlayer insulating layer 113 and may be configured by a single layer or a double layer of silicon oxide (SiOₓ) or silicon nitride (SiNₓ), but is not limited thereto.

The source electrode SE and the drain electrode DE of the driving transistor DT may be disposed on the interlayer insulating layer 113.

The source electrode SE and the drain electrode DE may be connected to one side and the other side of the active layer ACT, respectively, through contact holes provided in the interlayer insulating layer 113 and the gate insulating layer 112. The source electrode SE and the drain electrode DE may be formed of various conductive materials, such as magnesium (Mg), aluminum (Al), nickel (Ni), chromium (Cr), molybdenum (Mo), tungsten (W), gold (Au), or an alloy thereof, but are not limited thereto.

A portion of the active layer ACT overlapping the gate electrode GE is a channel region. One of the source electrode SE and the drain electrode DE is connected to one side of the channel region in the active layer ACT, and the other is connected to the other side of the channel region in the active layer ACT.

The passivation layer 114 may be disposed on the source electrode SE and the drain electrode DE. The passivation layer 114 is provided to protect the driving transistor DT and may be formed of an inorganic layer, for example, silicon oxide (SiOₓ), silicon nitride (SiNₓ), or a double layer thereof.

The first planarization layer 115a may be disposed on the passivation layer 114. The first planarization layer 115a may protect the driving transistor DT and planarize an upper portion thereof. The first planarization layer 115a may be configured by a single layer or a double layer, and for example, may be formed of photoresist or an acrylic organic material, but is not limited thereto.

The connection electrode CE may be disposed on the first planarization layer 115a.

The connection electrode CE may be connected to one of the source electrode SE and the drain electrode DE through a contact hole provided in the first planarization layer 115a.

A plurality of low potential power lines VSS is disposed on the first planarization layer 115a. For example, the plurality of low potential power lines VSS may be formed of an opaque conductive material such as titanium (Ti), gold (Au), silver (Ag), copper (Cu), molybdenum (Mo), aluminum (Al), or an alloy thereof, a conductive material such as indium tin oxide (ITO), or a stacked structure thereof, but is not limited thereto.

The second planarization layer 115b may be disposed on the connection electrode CE and the plurality of low potential power lines VSS. The second planarization layer 115b may be made of the same material as the first planarization layer 115a.

The light emitting element ED including the first electrode E1, the organic layer EL, and the second electrode E2 may be positioned on the second planarization layer 115b.

Hereinafter, a stack structure of the light emitting element ED will be described in detail.

The first electrode E1 may be disposed on the second planarization layer 115b. In this case, the first electrode E1 may be electrically connected to the connection electrode CE through a contact hole provided in the second planarization layer 115b. The first electrode E1 may be formed of a metallic material.

For example, when the display device 100 is a top emission type display device in which light emitted from the light emitting element ED is emitted above the substrate 110 on which the light emitting element ED is disposed, the first electrode E1 may include a transparent conductive layer and a reflective layer. The transparent conductive layer may be made of a transparent conductive oxide such as ITO or IZO, and the reflective layer may be made of, for example, silver (Ag), aluminum (Al), gold (Au), molybdenum (Mo), tungsten (W), chromium (Cr), or an alloy thereof.

The bank 116 may be disposed while covering the end of the first electrode E1 to define a light emission area. A portion of the bank 116 corresponding to the emission area of the sub-pixel SP may be opened. A part of the first electrode E1 may be exposed through the open part of the bank 116 (hereinafter, referred to as an open area). In this case, the bank 116 may be made of an inorganic insulating material, such as silicon nitride (SiNₓ) or silicon oxide (SiOₓ), or an organic insulating material, such as benzocyclobutene-based resin, acrylic-based resin, or imide-based resin, but is not limited thereto.

The bank 116 may be configured as a black bank 116 including a light absorbing material. For example, the light absorbing material may include carbon or black ink. The black bank 116 may prevent light emitted from the light emitting element ED from being directed to a side surface, thereby preventing color mixture between adjacent sub pixels SP and preventing reflection of external light. Furthermore, even if the polarization layer is not disposed, it is possible to prevent light leakage defects or the like.

The organic layer EL may be disposed on the bank 116. Accordingly, the organic layer EL may be disposed on the first electrode E1 exposed through the open area of the bank 116.

The organic layer EL is a layer for emitting light of a specific color and may have a structure separated for each sub pixel SP. For example, the organic layer EL disposed in the sub-pixel SP emitting red light may include an organic layer emitting red light, the organic layer EL disposed in the sub-pixel SP emitting green light may include an organic layer emitting green light, and the organic layer EL disposed in the sub-pixel SP emitting blue light may include an organic layer emitting blue light. Organic layers EL disposed in the sub pixel SP emitting red light, the sub pixel SP emitting green light, and the sub pixel SP emitting blue light may be separately disposed.

The second electrode E2 may be disposed on the organic layer EL and the bank 116.

The light emitting element ED may be formed by the first electrode E1, the organic layer EL, and the second electrode E2. The organic layer EL may include a plurality of organic material layers.

The encapsulation structure 117 (also referred to as ‘encapsulation part 117’ or ‘encapsulation unit 117’) may be located on the light emitting element ED described above.

The encapsulation part 117 may have a single-layered structure or a multi-layered structure. For example, the encapsulation part 117 may include a first encapsulation layer 117a, a second encapsulation layer 117b, and a third encapsulation layer 117c.

In this case, the first encapsulation layer 117a and the third encapsulation layer 117c may be configured by inorganic layers, and the second encapsulation layer 117b may be configured by an organic layer. Among the first encapsulation layer 117a, the second encapsulation layer 117b, and the third encapsulation layer 117c, the second encapsulation layer 117b is thickest and may serve as a planarization layer.

The first encapsulation layer 117a is disposed on the second electrode E2 and may be disposed to be most adjacent to the light emitting element ED. The first encapsulation layer 117a may be formed of an inorganic insulating material on which low-temperature deposition may be performed. For example, the first encapsulation layer 117a may be made of silicon nitride (SiNₓ), silicon oxide (SiOₓ), silicon oxynitride (SiON), or aluminum oxide (Al₂O₃). Since the first encapsulation layer 117a is deposited in a low temperature atmosphere, it is possible to prevent damage to the organic layer EL including an organic material vulnerable to a high temperature atmosphere during the deposition process.

The second encapsulation layer 117b may be formed to have a smaller area than that of the first encapsulation layer 117a. In this case, the second encapsulation layer 117b may be formed to expose both ends of the first encapsulation layer 117a. The second encapsulation layer 117b may serve as a buffer to alleviate stress between layers and to enhance planarization performance.

For example, the second encapsulation layer 117b may be made of an organic insulating material such as acrylic resin, epoxy resin, polyimide, polyethylene, or silicon oxycarbon (SiOC). For example, the second encapsulation layer 117b may be formed by an inkjet method, but is not limited thereto.

The third encapsulation layer 117c may be formed above the substrate 110 on which the second encapsulation layer 117b is formed so as to cover upper surfaces and side surfaces of the second encapsulation layer 117b and the first encapsulation layer 117a. In this case, the third encapsulation layer 117c may minimize or block the permeation of external moisture or oxygen into the first encapsulation layer 117a and the second encapsulation layer 117b. For example, the third encapsulation layer 117c may be made of an inorganic insulating material such as silicon nitride (SiNₓ), silicon oxide (SiOₓ), silicon oxynitride (SiON), or aluminum oxide (Al₂O₃).

A touch sensing structure (also referred to as ‘a touch sensing unit’) may be disposed on the encapsulation part 117 described above.

Specifically, the touch sensing unit may include a touch buffer layer 118a disposed on the encapsulation unit 117, a bridge electrode BE disposed on the touch buffer layer 118a, a touch interlayer insulating layer 118b disposed on the touch buffer layer 118a and the bridge electrode BE, and a plurality of touch electrodes TE disposed on the touch interlayer insulating layer 118b.

The touch buffer layer 118a may block a chemical solution such as a developer or an etching solution used in the manufacturing process of touch electrodes formed on the touch buffer layer 118a or external moisture or foreign substances from penetrating into the light emitting element.

The plurality of touch electrodes TE may include a plurality of first touch electrodes extending in a first direction and a plurality of second touch electrodes extending in a second direction intersecting the first direction.

For example, the plurality of first touch electrodes and the plurality of second touch electrodes may be disposed on the same layer. However, in an area where the plurality of first touch electrodes and the plurality of second touch electrodes intersect, the plurality of second touch electrodes may be separately disposed, and the plurality of separated second touch electrodes may be connected by the bridge electrode BE. A touch interlayer insulating layer 118b may be disposed between the plurality of second touch electrodes and the bridge electrode BE.

The first protective layer 119 may be disposed to cover the touch sensing unit. The first protective layer 119 may be formed of an organic insulating layer. The first protective layer 119 may protect the touch sensing unit and planarize an upper portion thereof. Further, the step formed at the upper layer of the display device 100 is prevented by the first protective layer 119 to improve the visibility of the display device 100.

The third buffer layer 120 may be disposed on the first protective layer 119. The third buffer layer 120 may reduce the penetration of moisture, oxygen, or impurities through the upper portion of the display device 100. For example, the third buffer layer 120 may be configured by a single layer or a double layer of silicon oxide (SiOₓ) or silicon nitride (SiNₓ), but is not limited thereto.

A black matrix BM may be disposed on the third buffer layer 120. For example, the black matrix BM may be provided in an integrated mesh shape to correspond to the non-emission areas of the plurality of light emitting elements ED, but is not limited thereto.

The black matrix BM may include a light absorbing material that absorbs a visible light wavelength band. That is, the black matrix BM may be a kind of light blocking member. For example, the black matrix BM may be made of a material that may be processed at a low temperature of about 100° C. or less, preferably about 85° C. or less. When the black matrix BM is made of a material capable of a low-temperature process, thermal damage to the light emitting element ED due to the formation of the black matrix BM may be minimized.

A plurality of anti-deposition patterns 130 may be disposed to at least partially overlap the black matrix BM, for example, overlapping in both plan and cross-sectional views as illustrated in the figures. For example, the black matrix BM and the plurality of anti-deposition patterns 130 may have the same width, and the plurality of anti-deposition patterns 130 may be disposed to be in contact with the bottom surface of the black matrix BM in the non-emission area of the light emitting element ED. That is, the plurality of anti-deposition patterns 130 may be disposed between the third buffer layer 120 and the black matrix BM.

The plurality of anti-deposition patterns 130 may include a fluorine-containing polymer such as a fluorine-containing oligomer, but is not limited thereto.

A plurality of metal patterns 140 may be disposed between a plurality of anti-deposition patterns 130. That is, each of the plurality of metal patterns 140 may be disposed between the plurality of anti-deposition patterns 130 on the third buffer layer 120. For example, the plurality of metal patterns 140 may include at least one selected from the group consisting of bismuth (Bi), nickel (Ni), and titanium (Ti), but is not limited thereto.

Specifically, the anti-deposition patterns 130 are disposed so as to correspond to the non-emission areas of the plurality of light emitting elements ED on the third buffer layer 120 by using fine metal masks (FMM), that is, to overlap the bank 116. Thereafter, a metal layer is deposited on the third buffer layer 120 and the plurality of anti-deposition patterns 130. In this case, due to the low surface energy of the upper surface of the plurality of anti-deposition patterns 130, the metal layer is not deposited on the plurality of anti-deposition patterns 130. A metal layer may be disposed in the form of a plurality of metal patterns 140 on a portion where a plurality of anti-deposition patterns 130 are not disposed, that is, on the third buffer layer between a plurality of anti-deposition patterns 130. In an embodiment, each of the anti-deposition patterns 130 may include an open area. The open areas of the anti-deposition patterns 130 may correspond to the emission areas of the plurality of light emitting elements ED.

As the plurality of metal patterns 140 is disposed between the plurality of anti-deposition patterns 130, the plurality of metal patterns 140 may be disposed between the black matrices BM. Specifically, the plurality of metal patterns 140 is disposed so as to correspond to the inside of the black matrix BM provided in the form of an integral mesh so as to correspond to the non-emission area of the plurality of light emitting elements ED, that is, between the emission area of the plurality of light emitting elements ED. Therefore, transmission and reflection performance in the emission area of the plurality of light emitting elements ED can be improved. In an embodiment, the plurality of metal patterns 140 may be respectively disposed in the open areas of the anti-deposition patterns 130. In other words, the plurality of metal patterns 140 may be disposed in the same layer as the plurality of anti-deposition patterns 130.

Meanwhile, when the plurality of metal patterns 140 is positioned higher than the black matrix BM, external light incident from the outside of the display device 100 is reflected by the plurality of metal patterns 140 before being absorbed into the black matrix BM, thereby increasing the reflectance of the light emitting element ED in the non-emission area. Accordingly, the plurality of metal patterns 140 may be located on the same layer as the black matrix BM or on a lower layer than the black matrix BM. Accordingly, external light incident from the outside of the display device 100 is absorbed by the black matrix BM in the non-emission area of the plurality of light emitting elements ED to reduce reflectance in the non-emission area.

The organic dye layer 150 may be disposed to cover the black matrix BM and the plurality of metal patterns 140. For example, the organic dye layer 150 may include a colorant such as a dye or pigment and a monomer.

The organic dye layer 150 may be formed by an application process such as inkjet or photo. For example, when the organic dye layer 150 is applied by the inkjet method, the black matrix BM disposed at the outermost side of the display panel may serve as an inkjet process dam.

The organic dye layer 150 may be integrally formed to correspond to the plurality of sub-pixels SP and configured to have a wavelength that transmits both red light, green light, and blue light. Accordingly, even though the plurality of light emitting elements ED disposed in each of the plurality of sub pixels SP emits red light, green light, or blue light, the organic dye layer 150 may transmit light emitted from each of the plurality of sub pixels SP.

Further, the organic dye layer 150 is integrally formed to correspond to the plurality of sub-pixels SP to simplify the manufacturing process and reduce the process cost and the process time compared to the case where the organic dye layer is separately formed for each sub-pixel.

The refractive index of the organic dye layer 150 may be 1.4 to 2, and the refractive index of the plurality of metal patterns 140 may be 1 or more. For example, total reflection is induced by a difference in refractive index at the boundary between the organic dye layer 150 and the plurality of metal patterns 140 to reduce reflectance of external light.

Meanwhile, the second protective layer 160 may be disposed to cover the organic dye layer 150. The second protective layer 160 may be formed of an organic insulating layer. The step formed on the uppermost layer of the display device 100 may be prevented by the second protective layer 160 to improve the visibility of the display device 100.

Although not shown, a cover member may be further disposed on the second protective layer 160. The cover member has a shape corresponding to the display panel and may be disposed to cover the display panel. The cover member may protect the display panel from external impacts, moisture, heat, and scratches. The cover member may be, for example, tempered glass, but is not limited thereto, and the cover member may be a flexible plastic cover that may be folded for thinness and flexibility of the display device 100.

For example, when the display device 100 further includes a cover member, the cover member may be fixed to the second protection layer 160 by an adhesive layer. The adhesive layer may minimize the occurrence of foreign substances or bubbles between the second protective layer 160 and the cover member, and may use an optically transparent adhesive such as an optically clear adhesive (OCA) or an optically transparent resin (OCR), but is not limited thereto.

Conventionally, a display device having a structure in which a polarizing plate is attached to a display panel has been used. However, when the polarizing plate is separately attached, there is a problem that the thickness of the display device increases. To overcome this, a color filter is disposed in the display panel to replace the polarization layer. However, in this case, there is a problem in that a mask process for patterning the color filter is added as the color filter is disposed for each sub-pixel, thereby increasing process cost and process time. Accordingly, instead of a color filter separated for each sub pixel in the display panel, an organic dye layer integrated in the plurality of sub pixels is disposed, and a metal layer is disposed under the organic dye layer to supplement transmission and reflection performance. Accordingly, it is possible to reduce the thickness of the display device, reduce the mask process, reduce the process cost and the process time, and improve the reflectance of external light. However, in this case, there is a problem in that a metal layer is also disposed in the non-emission area of the plurality of light-emitting elements to increase reflectance in the non-emission area of the plurality of light-emitting elements.

Accordingly, in the display device 100 according to the exemplary embodiment of the present disclosure, the black matrix BM and the plurality of anti-deposition patterns 130 are disposed to correspond to the non-emission area of the plurality of light emitting elements ED, the plurality of metal patterns 140 is disposed between the plurality of anti-deposition patterns 130, that is, the emission area of the plurality of light emitting elements ED, and the organic dye layer 150 is disposed to overlap the emission area and the non-emission area of the plurality of light emitting elements ED, thereby improving the reflectance in the emission area of the plurality of light emitting elements ED and reducing the reflectance in the non-emission area of the plurality of light emitting elements ED by not disposing unnecessary metal layers or metal patterns in the non-emission area of the plurality of light emitting elements ED.

Further, in the display device 100 according to the exemplary embodiment of the present disclosure, the organic dye layer 150 integrally formed in the plurality of sub pixels SP is disposed by an application process such as inkjet or photo to reduce the thickness of the display device 100 and reduce process cost and process time by not performing a mask process.

Further, in the display device 100 according to the exemplary embodiment of the present disclosure, the low-temperature black matrix BM and the black bank 116 are disposed in the non-emission area of the plurality of light emitting elements ED to prevent light emitted from the plurality of light emitting elements ED from being directed to the non-emission area of the plurality of light emitting elements ED. Accordingly, even if the polarization layer is not disposed, reflectance in the non-emission area of the plurality of light emitting elements ED may be reduced, and light leakage defects may be prevented.

Accordingly, in the display device 100 according to the exemplary embodiment of the present disclosure, even if the polarization layer is not disposed, a viewing angle may be secured at the same level as the display device in which the polarization layer is disposed, and reflection of external light may be reduced, thereby improving luminance and reducing power consumption.

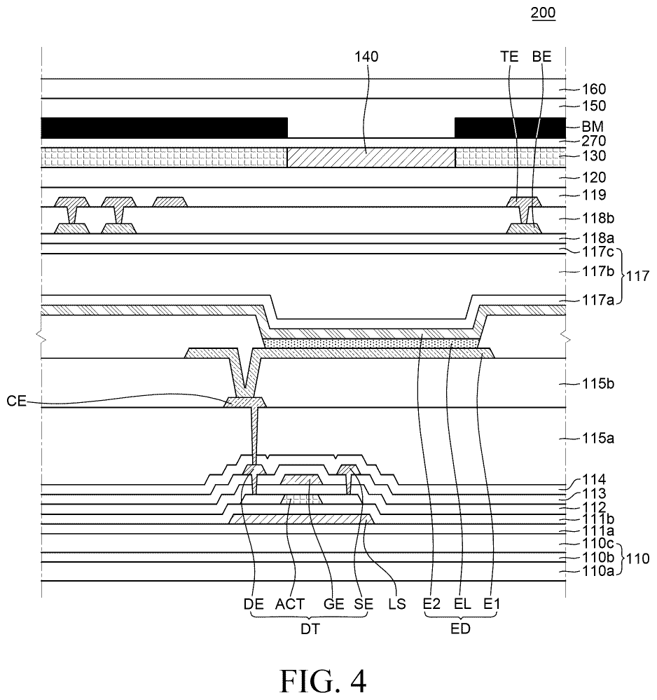

FIG. 4 is a schematic cross-sectional view of a display device according to another embodiment of the present specification. The display device 200 of FIG. 4 has the substantially same configuration as the display device 100 of FIGS. 1 to 3, except for the fourth buffer layer 270, so that a redundant description will be omitted.

Referring to FIG. 4, the display device 200 according to another exemplary embodiment of the present disclosure may further include a fourth buffer layer 270 disposed to cover the plurality of anti-deposition patterns 130 and the metal pattern 140. In this case, the black matrix BM may be disposed on the fourth buffer layer 270. That is, the plurality of anti-deposition patterns 130 may be disposed between the third buffer layer 120 and the fourth buffer layer 270.

For example, the fourth buffer layer 270 may be disposed between the plurality of anti-deposition patterns 130 and the organic dye layer 150 to prevent interference between the plurality of anti-deposition patterns 130 made of an organic material and the organic dye layer 150.

In addition, the fourth buffer layer 270 may reduce the penetration of moisture, oxygen, or impurities through the upper portion of the display device 100.

For example, the fourth buffer layer 270 may be configured as a single layer or multilayer made of silicon oxide (SiOₓ), silicon nitride (SiNₓ), and silicon oxynitride (SiON). However, the present disclosure is not limited thereto.

In the display device 200 according to another embodiment of the present specification, the black matrix BM and the plurality of anti-deposition patterns 130 are disposed to correspond to the non-emission area of the plurality of light emitting elements ED, the plurality of metal patterns 140 is disposed between the plurality of anti-deposition patterns 130, that is, the emission area of the plurality of light emitting elements ED, and the organic dye layer 150 is disposed to overlap the emission area and the non-emission area of the plurality of light emitting elements ED, thereby improving the reflectance in the emission area of the plurality of light emitting elements ED and reducing the reflectance in the non-emission area of the plurality of light emitting elements ED by not disposing unnecessary metal layers or metal patterns in the non-emission area of the plurality of light emitting elements ED. Accordingly, in the display device 200 according to another exemplary embodiment of the present disclosure, even if the polarization layer is not disposed, the viewing angle may be secured at the same level as the display device in which the polarization layer is disposed, and the reflection of external light may be reduced, thereby improving luminance and reducing power consumption.

Further, in the display device 200 according to another exemplary embodiment of the present disclosure, a buffer layer 270 made of an inorganic material is disposed between the plurality of anti-deposition patterns 130 made of an organic material and the organic dye layer 150 to suppress interference between two layers made of an organic material, thereby improving the stability of the display device 200.

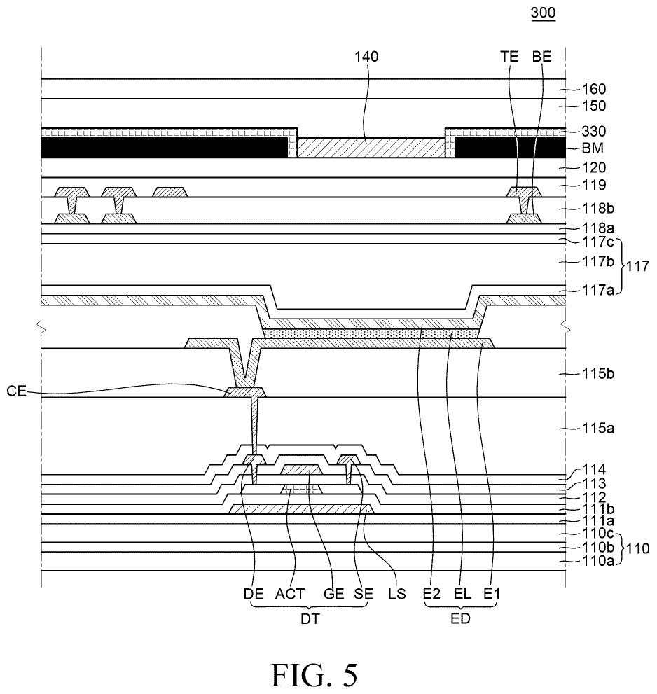

FIG. 5 is a schematic cross-sectional view of a display device according to still another exemplary embodiment of the present disclosure. A display device 300 of FIG. 5 has the substantially same configuration as the display device 100 of FIGS. 1 to 3, except for the positional relationship between the black matrix BM and the plurality of anti-deposition patterns 330, so that a redundant description will be omitted.

Referring to FIG. 5, in the display device 300 according to still another exemplary embodiment of the present disclosure, the black matrix BM may be disposed on the third buffer layer 120. For example, the black matrix BM may be provided in an integrated mesh shape to correspond to the non-emission areas of the plurality of light emitting elements ED, but is not limited thereto.

The black matrix BM may include a light absorbing material that absorbs a visible light wavelength band. That is, the black matrix BM may be a kind of light blocking member. For example, the black matrix BM may be made of a material that may be processed at a low temperature of about 100° C. or less, preferably about 85° C. or less. When the black matrix BM is made of a material capable of a low-temperature process, thermal damage to the light emitting element ED due to the formation of the black matrix BM may be minimized.

In the display device 300 according to another exemplary embodiment of the present disclosure, a plurality of anti-deposition patterns 330 may be disposed to cover upper surface UPS and side surfaces SSS of the black matrix BM.

The plurality of anti-deposition patterns 330 may include a fluorine-containing polymer such as a fluorine-containing oligomer, but is not limited thereto.

A plurality of metal patterns 140 may be disposed between the plurality of anti-deposition patterns 330 on the plurality of third buffer layers 120. For example, the plurality of metal patterns 140 may include at least one selected from the group consisting of bismuth (Bi), nickel (Ni), and titanium (Ti).

Specifically, the black matrix BM is formed on the third buffer layer 120 in the form of an integrated mesh so as to correspond to the non-emission areas of the plurality of light emitting elements ED. Subsequently, a plurality of anti-deposition patterns 330 is disposed to cover upper and side surfaces of the plurality of black matrices BM using fine metal masks (FMM). Thereafter, a metal layer is deposited on the third buffer layer 120 and the plurality of anti-deposition patterns 330. In this case, due to the low surface energy of the upper surface of the plurality of anti-deposition patterns 330, the metal layer is not deposited on the plurality of anti-deposition patterns 130. A metal layer may be disposed in the form of a plurality of metal patterns 140 on a portion where a plurality of anti-deposition patterns 130 are not disposed, that is, between a plurality of anti-deposition patterns 130.

As the plurality of metal patterns 140 is disposed between the plurality of anti-deposition patterns 330, the plurality of metal patterns 140 may be disposed between the black matrices BM. Specifically, the plurality of metal patterns 140 is disposed so as to correspond to the inside of the black matrix BM provided in the form of an integral mesh so as to correspond to the non-emission area of the plurality of light emitting elements ED, that is, between the emission area of the plurality of light emitting elements ED to improve transmission and reflection performance in the emission area of the plurality of light emitting elements ED.

Further, the plurality of metal patterns 140 may be located on the same layer as the black matrix BM or on a lower layer than the black matrix BM. Accordingly, external light incident from the outside of the display device 300 is absorbed by the black matrix BM in the non-emission area of the plurality of light emitting elements ED to reduce reflectance in the non-emission area.

In the display device 300 according to still another exemplary embodiment of the present disclosure, the black matrix BM and the plurality of anti-deposition patterns 330 are disposed so as to correspond to the non-emission area of the plurality of light emitting elements ED, the plurality of metal patterns 140 is disposed between the plurality of anti-deposition patterns 330, that is, the emission area of the plurality of light emitting elements ED, and the organic dye layer 150 is disposed so as to overlap the emission area and the non-emission area of the plurality of light emitting elements ED, thereby improving the reflectance in the emission area of the plurality of light emitting elements ED and reducing the reflectance in the non-emission area of the plurality of light emitting elements ED by not disposing unnecessary metal layers or metal patterns in the non-emission area of the plurality of light emitting elements ED. Accordingly, in the display device 300 according to another exemplary embodiment of the present disclosure, even if the polarization layer is not disposed, the viewing angle may be secured at the same level as the display device in which the polarization layer is disposed, and the reflection of external light may be reduced, thereby improving luminance and reducing power consumption.

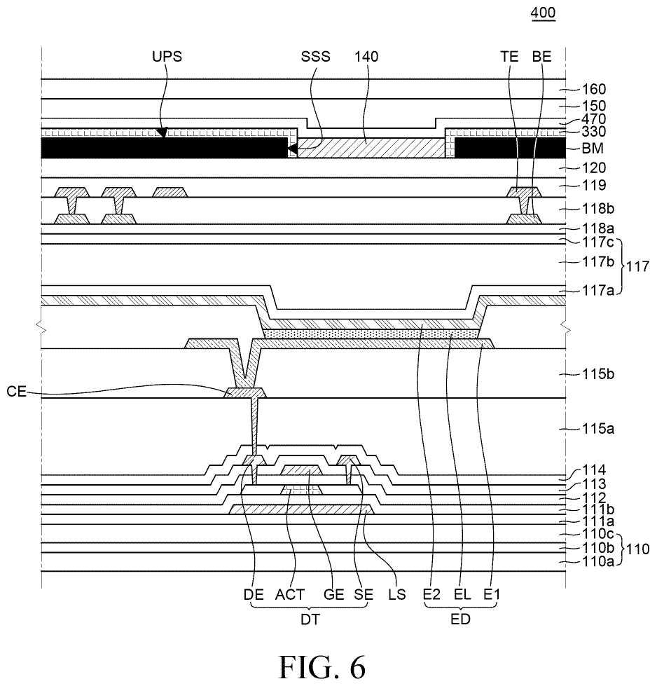

FIG. 6 is a schematic cross-sectional view of a display device according to still another exemplary embodiment of the present disclosure. The display device 400 of FIG. 6 has the substantially same configuration as the display device 300 of FIG. 5, except for the fourth buffer layer 470, so that a redundant description will be omitted.

Referring to FIG. 6, the display device 400 according to still another exemplary embodiment of the present disclosure may further include a fourth buffer layer 470 disposed to cover the plurality of anti-deposition patterns 330 and the metal pattern 140. In this case, the black matrix BM may be disposed on the fourth buffer layer 470. That is, the plurality of anti-deposition patterns 330 may be disposed between the black matrix BM and the fourth buffer layer 470.

For example, the fourth buffer layer 470 may be disposed between the plurality of anti-deposition patterns 330 made of an organic material and the organic dye layer 150 to prevent interference between the plurality of anti-deposition patterns 330 made of an organic material and the organic dye layer 150.

In addition, the fourth buffer layer 470 may reduce the penetration of moisture, oxygen, or impurities through the upper portion of the display device 100.

For example, the fourth buffer layer 470 may be configured as a single layer or multilayer made of silicon oxide (SiOₓ), silicon nitride (SiNₓ), and silicon oxynitride (SiON). However, the present disclosure is not limited thereto.

In the display device 400 according to still another embodiment of the present specification, the black matrix BM and the plurality of anti-deposition patterns 330 are disposed so as to correspond to the non-emission area of the plurality of light emitting elements ED, the plurality of metal patterns 140 is disposed between the plurality of anti-deposition patterns 330, that is, the emission area of the plurality of light emitting elements ED, and the organic dye layer 150 is disposed so as to overlap the emission area and the non-emission area of the plurality of light emitting elements ED, thereby improving the reflectance in the emission area of the plurality of light emitting elements ED and reducing the reflectance in the non-emission area of the plurality of light emitting elements ED by not disposing unnecessary metal layers or metal patterns in the non-emission area of the plurality of light emitting elements ED. Accordingly, in the display device 400 according to another exemplary embodiment of the present disclosure, even if the polarization layer is not disposed, a viewing angle may be secured at the same level as the display device in which the polarization layer is disposed, and reflection of external light may be reduced, thereby improving luminance and reducing power consumption.

Further, in the display device 400 according to another exemplary embodiment of the present disclosure, a buffer layer 470 made of an inorganic material is disposed between the plurality of anti-deposition patterns 330 made of an organic material and the organic dye layer 150 to suppress interference between two layers made of an organic material, thereby improving the stability of the display device 400.

The Exemplary Embodiment of the present disclosure can also be described as follows:

According to an aspect of the present disclosure, a display device includes a substrate including an active area in which a plurality of sub pixels is disposed and a non-active area surrounding the active area, a plurality of light emitting elements disposed in the plurality of sub pixels on the substrate, an encapsulation unit disposed to cover the plurality of light emitting elements, a touch sensing unit disposed on the encapsulation unit and including a plurality of touch electrodes, a black matrix disposed on the touch sensing unit, a plurality of anti-deposition patterns disposed to at least partially overlap the black matrix, a plurality of metal patterns disposed between the plurality of anti-deposition patterns, and an organic dye layer disposed on the black matrix.

According to another feature of the present specification, the width of the black matrix and the plurality of anti-deposition patterns may be the same.

The plurality of metal patterns may be located on the same layer as the black matrix or on a lower layer than the black matrix, and the plurality of metal patterns may be disposed between the black matrices.

According to another feature of the present specification, the plurality of anti-deposition patterns may be disposed to contact the lower surface of the black matrix.

The display apparatus may further include a buffer layer disposed to cover the plurality of anti-deposition patterns and the plurality of metal patterns, and the black matrix may be disposed on the buffer layer.

According to another feature of the present specification, the plurality of anti-deposition patterns may be disposed to cover the upper surface and the side surface of the black matrix.

According to another feature of the present specification, a buffer layer disposed to cover the plurality of anti-deposition patterns and the plurality of metal patterns may be further included.

According to another feature of the present specification, the refractive index of the organic dye layer may be 1.4 to 2, and the refractive index of the plurality of metal patterns may be 1 or more.

According to another aspect of the present disclosure, a display device includes a substrate, a plurality of light emitting elements disposed on the substrate, an encapsulation unit disposed to cover the plurality of light emitting elements, a touch sensing unit disposed on the encapsulation unit and including a plurality of touch electrodes, a plurality of metal patterns disposed on the touch sensing unit to overlap an organic layer of the plurality of light emitting elements, a plurality of fluorine-containing patterns disposed between the plurality of metal patterns on a plane, a black matrix disposed to overlap the plurality of fluorine-containing patterns, and an organic dye layer disposed on the black matrix, in which the plurality of metal patterns is disposed on the same layer as the black matrix or lower layer than the black matrix.

According to another feature of the present specification, the plurality of fluorine-containing patterns may be disposed to contact the lower surface of the black matrix.

The display device may further comprise a buffer layer disposed to cover the plurality of fluorine-containing patterns and the plurality of metal patterns, wherein the black matrix may be disposed on the buffer layer.

According to another feature of the present specification, the plurality of fluorine-containing patterns may be disposed to cover upper and side surfaces of the black matrix.

According to another feature of the present specification, a buffer layer disposed to cover the plurality of fluorine-containing patterns and the plurality of metal patterns may be further included.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. All the technical concepts in the equivalent scope of the present disclosure should be construed as falling within the scope of the present disclosure.

The various embodiments described above can be combined to provide further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a substrate including an active area in which a plurality of sub-pixels is disposed and a non-active area adjacent to the active area;
a plurality of light emitting elements disposed in the plurality of sub-pixels on the substrate, respectively;
an encapsulation unit disposed to cover the plurality of light emitting elements;
a touch sensing unit disposed on the encapsulation unit and including a plurality of touch electrodes;
a black matrix disposed on the touch sensing unit;
a plurality of anti-deposition patterns disposed to at least partially overlap the black matrix;
a plurality of metal patterns disposed in areas between the plurality of anti-deposition patterns; and
an organic dye layer disposed on the black matrix.

2. The display device according to claim 1, wherein the black matrix and the plurality of anti-deposition patterns have the same width.

3. The display device according to claim 2, wherein the plurality of metal patterns is disposed on the same layer as the black matrix or on a lower layer than the black matrix, and the plurality of metal patterns is disposed between adjacent portions of the black matrix.

4. The display device according to claim 3, wherein the plurality of anti-deposition patterns is disposed to be in contact with a lower surface of the black matrix.

5. The display device according to claim 4, further comprising:
a buffer layer disposed to cover the plurality of anti-deposition patterns and the plurality of metal patterns,
wherein the black matrix is disposed on the buffer layer.

6. The display device according to claim 1, wherein the plurality of anti-deposition patterns is disposed to cover upper and side surfaces of the black matrix.

7. The display device of claim 6, further comprising:
a buffer layer disposed to cover the plurality of anti-deposition patterns and the plurality of metal patterns.

8. The display device according to claim 1, wherein a refractive index of the organic dye layer is 1.4 to 2, and a refractive index of the plurality of metal patterns is 1 or more.

9. A display device comprising:
a substrate;
a plurality of light emitting elements disposed on the substrate;
an encapsulation unit disposed to cover the plurality of light emitting elements;
a touch sensing unit disposed on the encapsulation unit and including a plurality of touch electrodes;
a plurality of metal patterns disposed on the touch sensing unit to overlap an organic layer of the plurality of light emitting elements;
a plurality of fluorine-containing patterns disposed between the plurality of metal patterns on a plane;
a black matrix disposed to overlap the plurality of fluorine-containing patterns; and
an organic dye layer disposed on the black matrix,
wherein the plurality of metal patterns is disposed on the same layer as the black matrix or disposed on a layer beneath the black matrix.

10. The display device according to claim 9, wherein the plurality of fluorine-containing patterns is disposed to be in contact with the bottom surface of the black matrix.

11. The display device of claim 10 further comprising:
a buffer layer disposed to cover the plurality of fluorine-containing patterns and the plurality of metal patterns,
wherein the black matrix is disposed on the buffer layer.

12. The display device according to claim 9, wherein the plurality of fluorine-containing patterns is disposed to cover upper and side surfaces of the black matrix.

13. The display device of claim 12, further comprising:
a buffer layer disposed to cover the plurality of fluorine-containing patterns and the plurality of metal patterns.

14. A display device comprising:
a substrate including an active area in which a plurality of sub-pixels is disposed and a non-active area adjacent to the active area;
a plurality of light emitting elements disposed in the plurality of sub-pixels on the substrate, respectively;
a black matrix disposed on the plurality of light emitting elements and corresponding to non-emission areas of the plurality of light emitting elements;
a plurality of anti-deposition patterns disposed between the plurality of light emitting elements and black matrix, and at least partially overlapping with the black matrix;
a plurality of metal patterns disposed in the same layer as the plurality of anti-deposition patterns, and corresponding to emission areas of the plurality of light emitting elements; and
an organic dye layer disposed on the black matrix.

15. The display device according to claim 14, further comprising:
an encapsulation unit disposed to cover the plurality of light emitting elements.

16. The display device according to claim 15, further comprising:
a touch sensing unit disposed on the encapsulation unit and including a plurality of touch electrodes.
